(19) United States
(12) Patent Application Publication
(10) Pub. No.: US 2026/0293545 A1
(43) Pub. Date: Sep. 24, 2026

(54) PLASMA PRETREATMENT FOR SELECTIVE ADSORPTION OF AMINOSILANE INHIBITOR

(71) Applicant: Lam Research Corporation, Fremont, CA (US)

(72) Inventors: Rachel Anna NYE, Portland, OR (US); Subhendu PANDIT, Tualatin, OR (US); Nupur BIHARI, Tualatin, OR (US); William Todd NUNN, Lake Oswego, OR (US); Kapu Sirish REDDY, Portland, OR (US); Jason Nathaniel BELLING, Tualatin, OR (US)

(21) Appl. No.: 19/476,292

(22) PCT Filed: Apr. 18, 2024
(86) PCT No.: PCT/US2024/025275

§ 371 Date: Oct. 17, 2025

Related U.S. Application Data
(60) Provisional application No. 63/499,905, filed on May 3, 2023.

(51) Int. Cl. H10P 14/60; C23C 16/02; C23C 16/04; C23C 16/455; C23C 16/52; H01J 37/32

(52) U.S. Cl. CPC H10P 14/6514; C23C 16/0227; C23C 16/04; C23C 16/45544; C23C 16/52; H01J 37/32091; H01J 37/32357; H01J 37/32449; H10P 14/6339; H01J 2237/338

(57) ABSTRACT

Examples are disclosed that relate to adsorbing an aminosilane inhibitor selectively to a substrate surface using a dry process. One example provides a method for selectively depositing a film onto a first material of a substrate surface, the substrate surface also comprising a second material. The method comprises exposing the substrate surface to reactive species formed in a plasma. The method further comprises, after exposing the substrate surface to the reactive species formed in the plasma, exposing the substrate surface to an aminosilane inhibitor. The aminosilane inhibitor adsorbs to the second material in a higher concentration than the aminosilane inhibitor adsorbs to the first material of the substrate surface. The method further comprises depositing the film, wherein the aminosilane inhibitor on the second material inhibits deposition of the film onto the second material compared to deposition of the film onto the first material.

### BACKGROUND

In integrated circuit fabrication, metal lines can be embedded in dielectric material. Formation of such embedded metal lines involves patterning and etching of the dielectric material to form vias and trenches, followed by filling of these vias and trenches with a metal. Additional dielectric film layers may then be selectively deposited on the metal, thus generating metal lines that form conductive paths of an integrated circuit. However, as integrated circuit fabrication moves towards smaller technology nodes, it becomes technologically challenging to selectively deposit the dielectric film layers in accurate locations.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to adsorbing an aminosilane inhibitor selectively to a substrate surface using a dry process. One example provides a method for selectively depositing a film onto a first material of a substrate surface, the substrate surface also comprising a second material. The method comprises exposing the substrate surface to reactive species formed in a plasma. The method further comprises, after exposing the substrate surface to the reactive species formed in the plasma, exposing the substrate surface to an aminosilane inhibitor, thereby adsorbing the aminosilane inhibitor to the substrate surface. The aminosilane inhibitor adsorbs to the second material in a higher concentration than the aminosilane inhibitor adsorbs to the first material of the substrate surface. The method further comprises depositing the film onto the substrate surface, wherein the aminosilane inhibitor on the second material inhibits deposition of the film onto the second material as compared to deposition of the film on the first material.

In some such examples, the substrate surface is exposed to the aminosilane inhibitor without an air break following the exposure of the substrate surface to the reactive species formed in the plasma.

Additionally or alternatively, in some such examples, the method further comprises, following deposition of the film onto the substrate surface, re-exposing the substrate surface to the aminosilane inhibitor, and performing an additional deposition of the film onto the substrate surface.

Additionally or alternatively, in some such examples, the method further comprises, prior to re-exposing the substrate surface to the aminosilane inhibitor, removing at least some aminosilane inhibitor adsorbed to the substrate surface.

Additionally or alternatively, in some such examples, depositing the film comprises depositing the film using atomic layer deposition.

Additionally or alternatively, in some such examples, the second material comprises a dielectric material, and the first material comprises a metal material.

Additionally or alternatively, in some such examples, the second material comprises one or more of silicon dioxide, silicon oxynitride, silicon oxycarbide, silicon nitride, or cobalt, and the first material comprises one or more of tungsten, copper, molybdenum, titanium nitride, or tungsten oxide.

Additionally or alternatively, in some such examples, the aminosilane inhibitor comprises one or more of dimethylamino trimethyl silane, dimethylamino dimethyl silane, dimethylamino triethyl silane, diethylamino trimethylsilane, n-butyldimethyl(dimethylamino)silane, n-propyldimethyl(dimethylamino)silane, or triisopropyldimethylaminosilane.

Additionally or alternatively, in some such examples, the film is a dielectric film that comprises one or more of aluminum oxide, silicon nitride, titanium oxide, zinc oxide, silicon dioxide, hafnium oxide, tantalum nitride or titanium nitride.

Additionally or alternatively, in some such examples, exposing the substrate surface to the reactive species formed in the plasma comprises exposing the substrate surface to one or more of a capacitively coupled H₂/O₂ plasma, a capacitively coupled H₂ plasma, or a capacitively coupled He plasma.

Additionally or alternatively, in some such examples, exposing the substrate surface to the reactive species formed in the plasma comprises exposing the substrate surface to radicals generated in a remote plasma.

In another example, a processing tool comprises a processing chamber, and a substrate support disposed within the processing chamber. The substrate support is configured to support a substrate. The processing tool further comprises flow control hardware operable to control a flow of one or more processing chemicals to the processing chamber. The processing tool further comprises a radiofrequency power source configured to generate a plasma. The processing tool further comprises a controller. The controller is configured to control the processing tool to operate the radiofrequency power source and the flow control hardware to expose the substrate surface to reactive species formed in the plasma. The controller is further configured to, after operating the radiofrequency power source and the flow control hardware to expose the substrate surface to the reactive species formed in the plasma, operate the flow control hardware to control a flow of an aminosilane inhibitor from an aminosilane inhibitor source to expose the substrate surface to the aminosilane inhibitor, wherein the aminosilane inhibitor is configured to adsorb to the second material in a higher concentration than the first material. The controller is further configured to operate the flow control hardware to control a flow of a dielectric film precursor from a dielectric film precursor source to deposit a dielectric film onto the substrate surface.

In some such examples, the controller is further configured to control the flow control hardware to deposit the dielectric film onto the substrate surface without an air break following controlling the flow control hardware to expose the substrate surface to the aminosilane inhibitor.

Additionally or alternatively, in some such examples, the controller is further configured to control the flow control hardware to, following controlling the flow control hardware to deposit the dielectric film onto the substrate surface, operate the flow control hardware to control the flow of the aminosilane inhibitor from the aminosilane inhibitor source to re-expose the substrate surface to the aminosilane inhibitor, and operate the flow control hardware to control the flow of dielectric film precursor from the dielectric film precursor source to perform a second deposition of the dielectric film onto the substrate surface.

Additionally or alternatively, in some such examples, the controller is further configured to control the processing tool to, prior to re-exposing the substrate surface to the aminosilane inhibitor, control the flow control hardware and the plasma generator to remove at least some aminosilane inhibitor adsorbed to the substrate surface.

Additionally or alternatively, in some such examples, the controller is further configured to control the processing tool to deposit the dielectric film using atomic layer deposition.

Additionally or alternatively, in some such examples, the controller is further configured to control the processing tool to operate the radiofrequency power source to expose the substrate surface to a capacitively coupled H₂/O₂ plasma pretreatment, a capacitively coupled H₂ plasma pretreatment, or a capacitively coupled He plasma pretreatment. An H₂/O₂ plasma pretreatment is also referred to as an OH plasma pretreatment herein.

Additionally or alternatively, in some such examples, the controller is configured to operate the radiofrequency power source to expose the substrate surface to the plasma by operating the radiofrequency power source to expose the substrate surface to radical species from a remote plasma.

In another example, a method comprises exposing a substrate surface to reactive species formed in a plasma. After exposing the substrate surface to the reactive species formed in plasma, the substrate surface is exposed to an aminosilane inhibitor, the aminosilane inhibitor comprising one or more of dimethylamino trimethyl silane, dimethylamino dimethyl silane, dimethylamino triethyl silane, diethylamino trimethylsilane, n-butyldimethyl(dimethylamino)silane, n-propyldimethyl(dimethylamino)silane, or triisopropyldimethylaminosilane. The aminosilane inhibitor adsorbs to the dielectric material in a higher concentration than the aminosilane inhibitor adsorbs to the metal material. The method further comprises, without an air break following the exposure of the substrate surface to the aminosilane inhibitor, depositing a dielectric film onto the substrate surface. The aminosilane inhibitor on the dielectric material inhibits deposition of the dielectric film onto the dielectric material compared to deposition of the dielectric film on the metal material.

In some such examples, the dielectric material comprises silicon dioxide, and the metal material comprises tungsten.

### BRIEF DESCRIPTION OF THE DRAWINGS

FIG. 1 shows an example of a processing tool that can be used to selectively deposit a dielectric film onto a substrate surface.

FIG. 2 shows an example processing system comprising multiple processing tools.

FIG. 3 shows a flow diagram illustrating an example method for selective deposition of a film on a substrate following exposing the substrate to a plasma pretreatment and an aminosilane inhibitor.

FIGS. 4A-4E schematically show a cross-sectional view of a substrate at various stages of an example dielectric film deposition process.

FIG. 5 is a bar graph illustrating an increase in selectivity of an example aminosilane inhibitor based upon performing example plasma pretreatments.

FIG. 6 is a bar graph illustrating the relative effects of different example plasma pretreatments on selectivity of an example aminosilane inhibitor.

FIG. 7 is a bar graph illustrating the selectivity of an example aminosilane inhibitor as a function of different example plasma pretreatments.

FIG. 8 is a bar graph illustrating adsorption of an example aminosilane inhibitor as a function of a duration of aminosilane inhibitor exposure.

FIG. 9 is a bar graph illustrating adsorption of an example aminosilane precursor to different substrate surface materials with and without an example plasma pretreatment.

FIGS. 10A-10B are bar graphs illustrating effects of substrate temperature on selectivity of an example aminosilane inhibitor.

FIGS. 11A-11D schematically show a cross-sectional view of a substrate at various stages of a re-application of aminosilane inhibitor.

FIG. 12 shows a schematic diagram of an example computing system.

### DETAILED DESCRIPTION

The term “air break” generally refers to a process of exposing a substrate to air while transferring the substrate between processing tools.

The term “atomic layer deposition” (ALD) generally represents a process in which a film is formed on a substrate in one or more individual layers by sequentially adsorbing a precursor conformally to the substrate and reacting the adsorbed precursor to form a dielectric film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth” and “deposition”, and variants thereof, also may be used to refer to film formation.

The term “dielectric surface” generally represents a portion of a substrate surface comprising a dielectric material. The term “dielectric material” generally represents a material that can be polarized by an applied electric field. Examples of dielectric materials include silicon dioxide (SiO₂), doped SiO₂ (e.g., fluorine-doped and carbon-doped SiO₂), silicon nitride (Si₃N₄), silicon carbide (SiC), silicon oxycarbide (SiOₓC_{y}), silicon oxynitride (SiOₓN_{y}), and silicon carbon nitride (SiCₓN_{y}). These examples and other dielectric materials that incorporate silicon may be collectively referred to as silicon-containing dielectric materials.

The term “dielectric film” generally represents a layer of a dielectric material that is deposited on a substrate surface.

The term “dry process” generally represents a process or reaction that does not utilize exposure of a substrate to a solution.

The term “inhibitor” generally represents a molecule that can adsorb to a substrate surface to inhibit the growth of a film on the substrate surface. The term inhibitor can be used herein to represent an inhibitor molecule introduced into a processing chamber, reactive inhibitor species formed in a plasma, and adsorbed inhibitor on a substrate surface. The term “aminosilane inhibitor” generally represents an inhibitor comprising a silane compound in which a hydrogen is substituted by an amino group. Examples of aminosilane inhibitors include dimethylamino trimethyl silane, dimethylamino dimethyl silane, dimethylamino triethyl silane, diethylamino trimethylsilane, n-butyldimethyl(dimethylamino)silane, n-propyldimethyl(dimethylamino)silane, or triisopropyldimethylaminosilane. The terms “dry inhibitor” and “dry aminosilane inhibitor” generally represent inhibitor molecules that are not dissolved or suspended in a solvent for application to a substrate.

The term “plasma” generally represents a gas comprising cations and free electrons. A plasma can be used to generate reactive chemical species from a precursor molecule introduced into the plasma.

The term “remote plasma” generally refers to a system wherein the plasma is generated at a location remote to a processing chamber in which a substrate is being processed.

The term “in-situ plasma” generally represents a system wherein the plasma is generated within the processing chamber in which the substrate is being processed. An in-situ plasma can be formed between a showerhead electrode and a substrate holder electrode.

The term “plasma generator” refers generally to hardware configured to form a plasma for processing a substrate in a processing chamber. The term “capacitively coupled plasma” refers generally to a plasma in which energy for the plasma is supplied by an electric field generated between electrodes. The term “inductively coupled plasma” refers generally to a plasma in which energy for the plasma is supplied by electric currents produced by electromagnetic induction.

The term “reactive species formed in a plasma” generally refers to ions and/or radicals that are generated in a plasma and that are chemically reactive with a substrate surface.

The terms “pretreating”, “pretreatment”, and variants thereof generally represent subjecting a substrate to a process before exposing the substrate to an aminosilane inhibitor.

The term “substrate” generally represents any object on which a film can be deposited.

The term “substrate holder” generally represents any structure configured to support a substrate in a processing chamber.

As described above, depositing a film onto an underlying substrate layer with a correct alignment to the underlying layer becomes more and more challenging as the desired regions of the substrate surface for deposition become smaller and more complex. For example, it can be hard to accurately align a film being deposited with an underlying layer using photolithography. Some solutions to this issue involve the use of inhibitor molecules that selectively adsorb to some materials selectively over other materials on a substrate surface. The inhibitor molecules can be used to block certain regions of the substrate surface due to this selectivity. Films then can be deposited on unblocked substrate surfaces selectively over blocked substrate surfaces. The use of an inhibitor molecule avoids the difficulties encountered when using photolithography to align substrate layers.

For example, aminosilane inhibitors can be used to selectively adsorb to some substrate surfaces, such as tungsten surfaces, preferentially over other surfaces, such as silicon dioxide surfaces. The aminosilane inhibitors can block adsorption of a dielectric film precursor to the metal surface. This allows a dielectric film to be selectively deposited on the dielectric surface. Due to the selective adsorption of the inhibitor to the metal surface, the edge of the dielectric film can naturally align with the edge of the underlying dielectric surface as it grows.

Current methods for selectively adsorbing an aminosilane inhibitor to a dielectric surface can involve dipping the substrates into a liquid phase solution of inhibitor molecules. The inhibitor molecules deposited in such a wet process can adsorb to metal and dielectric surfaces with low selectivity. Thus a wet rinse can be performed to selectively remove adsorbed inhibitor from the metal surfaces. Example wet rinses can include rinses with water and/or isopropyl alcohol (IPA). Following such a rinse, the inhibitor will remain adsorbed to the dielectric surfaces, while the metal surfaces are exposed. This can enable dielectric film deposition on the metal surface without deposition of the dielectric film on the inhibited dielectric surface. Rinses are often followed by a drying step. The drying step can be performed with an inert gas, such as nitrogen and/or argon.

However, the combination of wet applications, rinses, and dry exposures is undesirable for throughput. This is because the multiple steps can require multiple separate tools and/or process delays that increase overall substrate processing times and complexity. Further, wet processing can result in oxidation of the metal surface. This can reduce selectivity of the inhibitor between the dielectric and metal surfaces. Also, one or more air breaks can occur when transferring the substrate between baths and/or chambers during such wet processing. Air breaks can adversely impact substrate surfaces. Still further, if the inhibitor is not fully removed from the dielectric surface during the rinse, the quality of the dielectric film deposited over the dielectric surface can be negatively impacted.

Accordingly, examples are disclosed that relate to the use of dry processes to selectively adsorb an aminosilane inhibitor to a substrate surface comprising a first material and a second material. As described in more detail below, the disclosed examples selectively adsorb an aminosilane inhibitor to the second (e.g., dielectric) surface compared to a first (e.g., metal) surface using a plasma pretreatment to differentiate surface chemistries. Then, the substrate is exposed to the aminosilane inhibitor. The aminosilane inhibitor adsorbs to the second material with sufficiently high selectivity compared to the first material to prevent subsequent film deposition on the second material, while permitting film deposition on the first material.

The disclosed examples also eliminate the use of a post-inhibitor treatment rinse. Once the aminosilane inhibitor is applied, the substrate surface is ready for dielectric film deposition. As described in more detail below, the disclosed example plasma pretreatments can increase the selectivity of aminosilane inhibitors on a variety of substrate surface material combinations. Further, the disclosed examples can allow dielectric films to be selectively deposited with fewer process steps than the use of a wet inhibitor application.

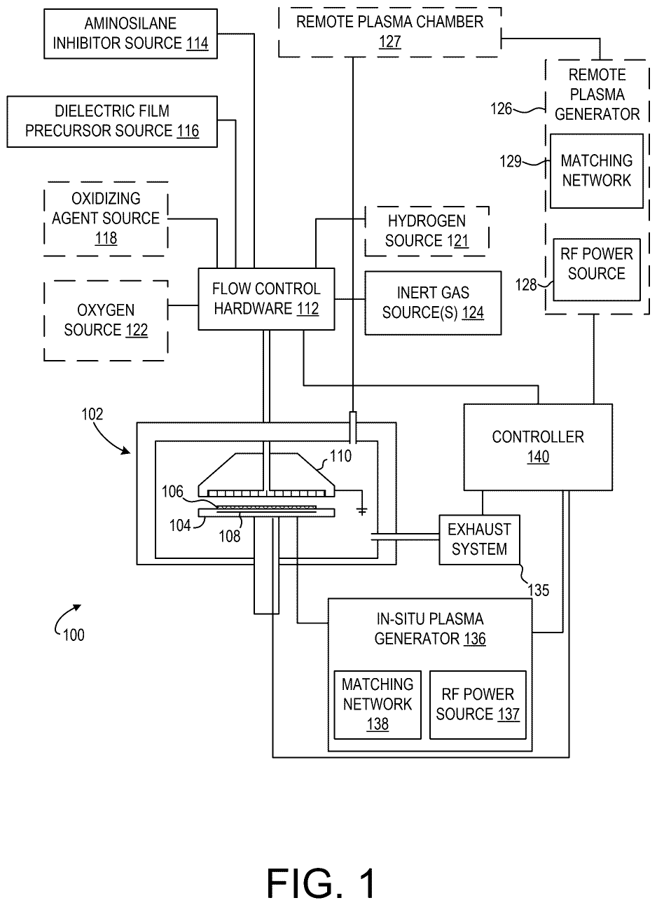

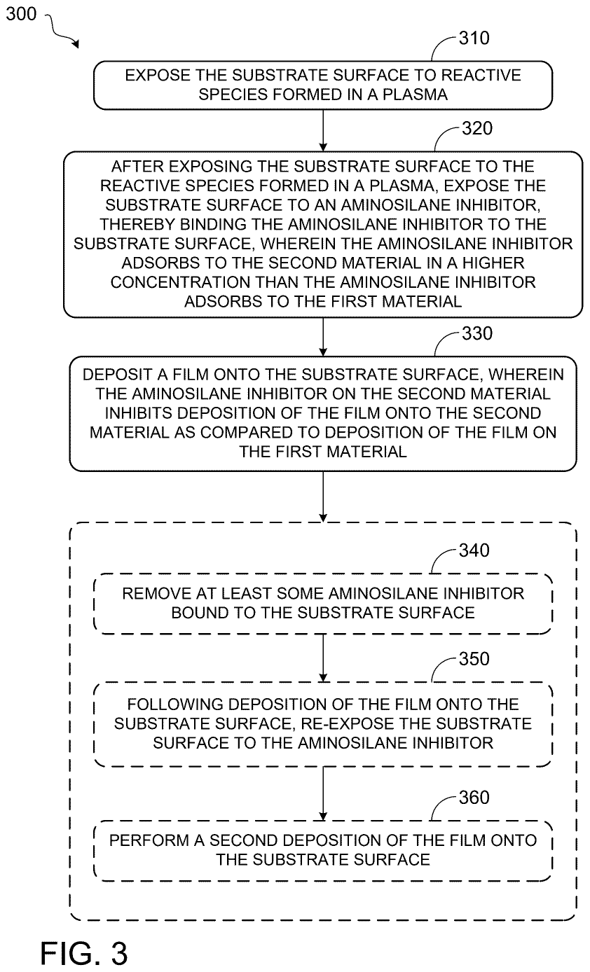

FIG. 1 shows an example of a processing tool 100 that can be used to perform a plasma pretreatment on a substrate. The processing tool also can be used to selectively adsorb an aminosilane inhibitor to the substrate, and/or selectively deposit a dielectric film on a substrate. Processing tool 100 is an example of a processing tool that can implement the methods described herein with reference to FIGS. 3, 4A-4E, and 11A-11D. In other examples, one or more of these processes can be performed using a different tool.

Processing tool 100 comprises a processing chamber 102 and a substrate support 104 within the processing chamber. Substrate support 104 is configured to support a substrate 106 disposed within processing chamber 102. Substrate support 104 can comprise a pedestal, such as an electrostatic chuck pedestal, or any other suitable structure. Substrate support 104 can comprise a substrate heater 108.

The processing tool 100 further comprises a showerhead 110. In other examples, a processing tool can comprise a nozzle or other apparatus for introducing gas into processing chamber 102, as opposed to or in addition to a showerhead. The processing tool 100 further comprises flow control hardware 112. Flow control hardware 112 connects processing gas source(s) to the processing chamber to allow a flow of each of one or more processing gases to be controlled. In the depicted example, the flow control hardware 112 connects an aminosilane inhibitor source 114, a film precursor source 116, an optional oxidizing agent source 118 (e.g., O₂, H₂O, H₂O₂, N₂O, other nitrogen oxides for forming dielectric films from film precursors, an optional hydrogen source 121 for forming plasma containing hydrogen, an optional oxygen source 122 for forming OH plasmas, one or more inert gas source(s) 124, and an optional remote plasma generator 126. The flow control hardware 112 can include any suitable components. Examples include mass flow controllers, valves, and conduits.

The aminosilane inhibitor source 114 comprises any suitable aminosilane inhibitor that can be introduced into a processing chamber in a gas phase (including liquid or solid materials that can be vaporized for introduction into the processing chamber) for selectively adsorbing to a substrate surface. Examples include dimethylamino trimethyl silane, dimethylamino dimethyl silane, dimethylamino triethyl silane, diethylamino trimethylsilane, n-butyldimethyl(dimethylamino)silane, n-propyldimethyl(dimethylamino)silane, or triisopropyldimethylaminosilane. In some examples, aminosilane inhibitor source 114 comprises an aminosilane inhibitor that is in a condensed phase at standard pressure and temperature. In such examples, aminosilane inhibitor source 114 can comprise a flow-over-vapor delivery system, a vaporizer delivery system, charged volume delivery system, a mole delivery device, or other suitable delivery system to volatilize the condensed phase aminosilane inhibitor. This enables the delivery of the aminosilane precursor in a vapor phase.

The film precursor source 116 comprises a volatile or volatilizable dielectric film precursor that can adsorb to a substrate surface and then be chemically converted into a film, such as by using atomic layer deposition. Example film precursors include dielectric film precursors. Example dielectric film precursors include precursors containing Al, Si, Ti, Zn, Si, Hf, Sn, and Ta. Other materials can also be deposited once the substrate surface has been treated with aminosilane inhibitor, such as W, Mo, Ta, Ru, Co, and Cu using suitable precursors. In some examples, the film precursor source 116 contains a film precursor that is in a condensed phase at standard pressure and temperature. In such examples, film precursor source 116 can comprise a flow-over vapor delivery system, a vaporizer delivery system, a charge volume delivery system, a mole delivery device, or other suitable delivery system to volatilize the condensed phase dielectric film precursor. For forming aluminum oxide dielectric films, example dielectric film precursors can comprise one or more of methyl aluminum propoxide, methyl aluminum isopropoxide, methyl aluminum butoxide, methyl aluminum t-butoxide, methyl aluminum ethoxide, dimethyl aluminum propoxide, dimethyl aluminum isopropoxide, dimethyl aluminum butoxide, dimethyl aluminum t-butoxide, dimethyl aluminum ethoxide, ethyl aluminum propoxide, ethyl aluminum isopropoxide, ethyl aluminum butoxide, ethyl aluminum t-butoxide, ethyl aluminum ethoxide, diethyl aluminum propoxide, diethyl aluminum isopropoxide, diethyl aluminum butoxide, diethyl aluminum t-butoxide, diethyl aluminum ethoxide, propyl aluminum propoxide, propyl aluminum isopropoxide, propyl aluminum butoxide, propyl aluminum t-butoxide, propyl aluminum ethoxide, dipropyl aluminum propoxide, dipropyl aluminum isopropoxide, dipropyl aluminum butoxide, dipropyl aluminum t-butoxide, or dipropyl aluminum ethoxide. For silicon dioxide or other silicon-containing oxides, such dielectric film precursors may comprise one or more of triethoxysilane, tetraethyl orthosilicate, tetramethoxysilane, methyl triethoxysilane, methyltrimethoxysilane, dimethyldimethoxysilane, trimethylmethoxysilane, dimethyldiethoxy silane, bis-triethoxysilylethane, bis-triethoxysilylmethane, tetramethylcyclotetrasiloxane, octamethylcyclotetrasiloxane, or tetravinyltetramethylcyclotetrasiloxane.%

The optional oxidizing agent source 118 can comprise any suitable oxidizing agent that can be introduced into a processing chamber to oxidize a film precursor to form a desired dielectric film. Where the dielectric film comprises an aluminum oxide film and the dielectric film precursor comprises trimethylaluminum, example oxidizing agents include water and alcohols. Example alcohols include methanol, ethanol, t-butyl alcohol, n-butyl alcohol, 2-butyl alcohol, and propanol. When the dielectric film comprises a silicon oxide film, the dielectric film precursor can comprise one or more of silanes, chlorosilanes, organosilanes, or heterosilanes. An example oxidizing agent includes oxygen. Other example co-reactants can include reactants for forming nitrides. An example reactant for forming nitrides is ammonia.

In some examples, an oxidizing agent can be in a condensed phase at standard pressure and temperature. In such examples, the oxidizing agent source 118 can comprise a flow-over vapor delivery system, a vaporizer delivery system, charged volume delivery system, a mole delivery device, or other suitable delivery system to volatilize the condensed phase oxidizing agent.

Inert gas source(s) 124 can comprise any suitable inert gas. Examples include helium, neon, argon, krypton, and xenon. In some applications, such as in processing steps that do not utilize a plasma, nitrogen (N₂) gas can be used as an inert gas. In some examples, one or more additional inert gas sources can be included, each providing a different inert gas.

In some examples, optional remote plasma generator 126 can be used to generate a remote plasma to provide reactive species for the deposition process. The term “remote plasma” refers generally to a plasma to which a substrate is not directly exposed during a deposition process. Instead, reactive species from a remote plasma diffuse to substrate 106. In the depicted example, remote plasma generator 126 is shown as controlling the formation of a plasma in a remote plasma chamber 127. The remote plasma chamber 127 is fluidly connected to processing chamber 102 so that radicals formed in the remote plasma chamber can diffuse into processing chamber 102. The remote plasma chamber comprises an inductive coil or capacitor plates (not shown) to form a plasma. In other examples, a remote plasma chamber can be contiguous with a processing chamber but located away from processing stations. Remote plasma generator 126 comprises a remote plasma radiofrequency (RF) power source 128 and a remote plasma matching network 129 for impedance matching of remote plasma RF power source 128.

Remote plasma RF power source 128 can be configured for any suitable frequency and power. Examples of suitable frequencies include 400 kHz, 13.56 MHZ, 27 MHz, 60 Mz, and 90 MHz. Examples of suitable powers include powers between 50 W (watts) and 6500 W. In some examples, remote plasma RF power source 128 can be configured to operate at a plurality of different frequencies and/or powers. In some examples, two or more different frequencies of radiofrequency power can be used together.

The processing tool 100 further comprises an exhaust system 135. The exhaust system 135 is configured to exhaust gases from the processing chamber 102. The exhaust system 135 can comprise any suitable hardware, including one or more low vacuum pumps and one or more high vacuum pumps.

The processing tool 100 further comprises an in-situ plasma generator 136 comprising an RF power source 137 that is electrically connected to substrate support 104. The showerhead 110 is grounded to form the other electrode. In other examples, the RF power source 137 can be connected to the showerhead 110 and the substrate support 104 can be grounded. In this manner, a capacitively coupled plasma can be formed between the showerhead 110 and the substrate support 104. The processing tool 100 further includes a matching network 138 for impedance matching of RF power source 137.

RF power source 137 can be configured to provide RF energy of any suitable frequency and power. Example frequencies include 400 kHz, 13.56 MHz, 27 MHz, 60 MHz, and 90 MHz. Example powers include powers of 50 W to 6500 W. This and other ranges stated herein are inclusive of the endpoints of the ranges. In some examples, RF power source 137 is configured to operate at a plurality of different frequencies and/or powers. In other examples, a processing tool can provide for other radiofrequency powers and/or frequencies. While processing tool 100 is illustrated as being configured to generate both a remote plasma and an in-situ plasma, in some examples, a processing tool can be configured to generate one of a remote plasma or an in-situ plasma.

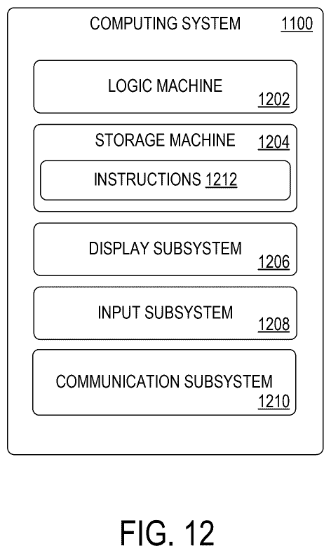

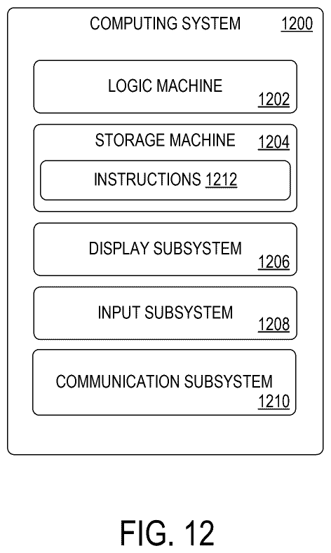

Controller 140 is operatively coupled to the substrate heater 108, flow control hardware 112, remote plasma generator 126, exhaust system 135, and in-situ plasma generator 136. Controller 140 is configured to control various functions of the processing tool 100 to selectively deposit a film on a substrate surface, such as a dielectric film. For example, controller 140 is configured to operate substrate heater 108 to heat a substrate to a desired temperature. Controller 140 also is configured to operate flow control hardware 112 and one or more of in-situ plasma generator 136 and remote plasma generator 126 to generate an in-situ plasma and/or a remote plasma generator 126, and to exposing a substrate surface to the reactive species formed in the plasma. Controller 140 is also configured to operate flow control hardware 112 to control a flow of aminosilane inhibitor from aminosilane inhibitor source 114 into processing chamber 102. Controller 140 is further configured to operate flow control hardware 112 to control a flow of film precursor from film precursor source 116 in order to deposit a film onto the substrate surface after exposing the substrate surface to the aminosilane inhibitor. Controller 140 can comprise any suitable computing system. Example computing systems are described below with reference to FIG. 12.

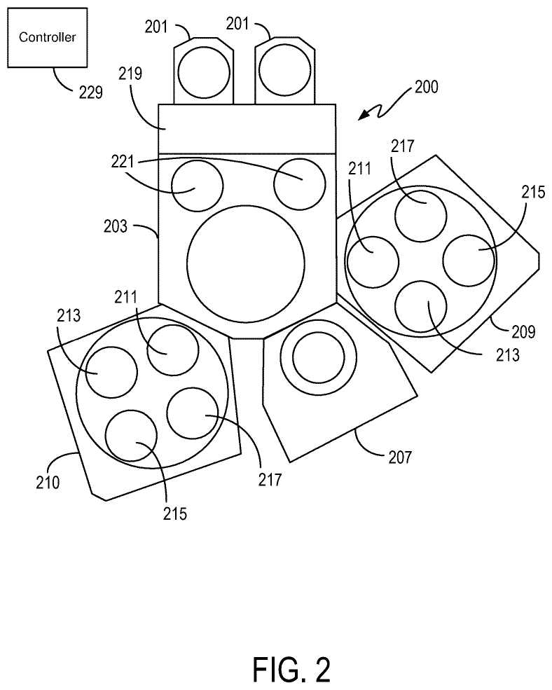

In some examples, various processes described herein can be performed in different processing tools that are integrated into a common processing system. FIG. 2 is a schematic view of a processing system 200 that comprises multiple processing tools coupled by a transfer module 203. The transfer module 203 provides a clean, pressurized environment to avoid contamination of substrates being processed as they are moved between various processing tools. Mounted on transfer module 203 are two multi-station processing tools 209 and 210. In some examples, each processing tool 209 and 210 can be capable of performing one or more of generating a plasma and exposing a substrate surface to the reactive species formed in the plasma, exposing a substrate to an aminosilane inhibitor, and/or controlling a flow of a dielectric film precursor to deposit a dielectric film onto the substrate surface.

Processing tools 209 and 210 each comprise multiple processing stations 211, 213, 215, and 217 that can sequentially or non-sequentially perform any of the methods and/or processes described herein. The processing stations 211, 213, 215, and 217 in each of processing tools 209 and 210 can include a heated pedestal and a showerhead. Processing tool 100 is an example of processing tools 209 and 210 and can be implemented as processing stations 211, 213, 215, and/or 217.

Also mounted on the transfer module 203 can be one or more single or multi-station process modules, such as process module 207, capable of performing plasma pretreatments, or any other processes described in relation to the described methods. The process module 207 can be used, for example, to expose a substrate to an aminosilane inhibitor, to perform a plasma pretreatment, to expose the substrate to dielectric film precursors, etc. Processing tool 100 is an example of process module 207.

System 200 also includes one or more substrate source modules 201, where substrates are stored before and after processing. An atmospheric robot (not shown) in atmospheric transfer chamber 219 can first remove substrates from the source modules 201 to load locks 221. A substrate transfer device (for example, a robot arm unit) in transfer module 203 moves the substrates from load locks 221 to and among the modules mounted on transfer module 203.

In various examples, a controller 229 is employed to control process conditions during deposition. The controller 229 can include one or more memory devices and one or more processors. A processor can include a CPU or computer, analog and/or digital input/output connections, stepper motor controller boards, etc. Example hardware for the controller 229 is described in more detail below and with regard to FIG. 12.

The controller 229 can control all of the activities of the deposition apparatus. The system controller 229 executes system control software, including sets of instructions for controlling the timing, mixture of processing chemicals, chamber pressure, chamber temperature, substrate temperature, RF power levels for plasma pretreatments, substrate chuck or pedestal position, and other parameters of a particular process. Other computer programs stored on memory devices associated with the controller 229 can be employed in some examples.

In some examples, the controller 229 comprises a user interface. The user interface can include a display screen, graphical software displays of the apparatus and/or process conditions, and user input devices such as pointing devices, keyboards, touch screens, microphones, etc.

The controller parameters relate to process conditions, such as, for example, process gas composition and flow rates, temperature, pressure, cooling gas pressure, substrate temperature, and chamber wall temperature. These parameters are provided to the user in the form of a recipe and can be entered utilizing the user interface. Signals for monitoring the process can be provided by analog and/or digital input connections of the system controller 229. The signals for controlling the process are output on the analog and digital output connections of the system 200.

The system software can be designed or configured in a plurality of different ways. For example, various chamber component subroutines or control objects can be written to control operation of the chamber components involved in carrying out the deposition processes (and other processes, in some cases) in accordance with the methods and processes described herein. Examples of programs or sections of programs for this purpose include substrate positioning code, process gas control code, pressure control code, and heater control code. Example hardware for controller 229 is described below with regard to FIG. 12.

FIG. 3 shows a flow-diagram for an example method 300 for selectively depositing a film, such as a dielectric film, onto a first material of a substrate surface, the substrate surface also comprising a second material. For example, method 300 may be used to selectively adsorb aminosilane inhibitors to a dielectric substrate surface (e.g. silicon dioxide) without blocking film deposition onto the first material (e.g. tungsten).

As an example, method 300 may be executed by a controller, such as controllers 140 or 229 as described with regard to FIGS. 1 and 2 to control a processing tool or processing system, such as processing tool 100 or processing system 200, to perform method 300.

In some such examples, the second material can comprise a silicon-containing dielectric material, and the first material can comprise a metal. As more specific examples, the second material can comprise one or more of silicon dioxide, silicon nitride, silicon oxynitride, silicon oxycarbide, or silicon oxycarbonitride, including doped versions thereof. In other examples, the second material can comprise cobalt. In some examples, the first material can comprise one or more of tungsten, copper, molybdenum, titanium nitride, or tungsten oxide. As tungsten may possess several oxidation states, the term “tungsten oxide” may refer to at least tungsten (III) oxide, tungsten (IV) oxide (i.e., tungsten dioxide), tungsten (VI) oxide (i.e. tungsten trioxide), or tungsten pentoxide.

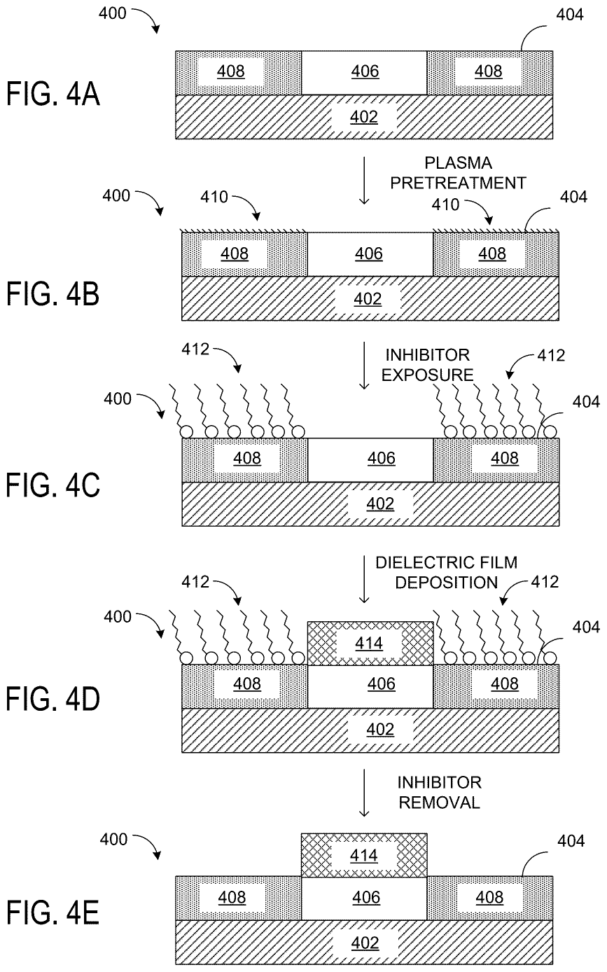

FIGS. 4A-4E show a cross-sectional view of a substrate 400 at various stages in a selective dielectric material deposition process. Referring first to FIG. 4A, substrate 400 comprises an underlayer 402 of arbitrary composition. Substrate 400 further comprises a substrate surface 404 comprising a first material 406 and second material 408. In this example, first material 406 will be described as a metal material. An example is tungsten. Second material 408 will be described as a dielectric material. An example is silicon dioxide. However, as described elsewhere herein, other surface compositions may be employed for the selective adsorption of an aminosilane inhibitor.

Returning to FIG. 3, at 310, method 300 comprises performing a plasma pretreatment by exposing the substrate surface to reactive species formed in a plasma. Exposing the substrate surface to such a plasma pretreatment can enhance the selectivity of an aminosilane inhibitor for various combinations of substrate surface materials compared to omitting the plasma pretreatment. For example, performing a plasma pretreatment can enhance selective adsorption of the aminosilane inhibitor on dielectric surfaces such as silicon dioxide, silicon oxynitride, silicon oxycarbide, silicon nitride, or cobalt with respect to other materials, such as tungsten, copper, molybdenum, titanium nitride, or tungsten oxide.

In various examples, the plasma pretreatment can comprise an in-situ plasma and/or a remote plasma, as described with regard to FIG. 1. An in-situ plasma can comprise a capacitively coupled plasma (CCP) or an inductively coupled plasma (ICP). A remote plasma typically comprises an ICP but can alternatively or additionally can comprise a CCP. Any suitable gas mixtures can be used in a plasma pretreatment. Examples include H₂ plasmas, H₂/O₂ (OH) plasmas, and He plasmas.

FIG. 4B shows substrate surface 404 following a plasma pretreatment. Second material 408 is shown as being modified by plasma to comprise surface groups 410 to which an aminosilane inhibitor can adsorb, while first material 406 is unchanged. Example surface groups include —OH, —H, and —NH groups. Example surface groups also can include surface terminations comprising a bridge, e.g. —Si—O—Si wherein either of the O or Si group in the bridge can react with aminosilanes.

Returning to FIG. 3, at 320 method 300 includes, after exposing the substrate surface to the reactive species formed in the plasma, exposing the substrate surface to an aminosilane inhibitor. The aminosilane inhibitor adsorbs to the second material in a higher concentration than the aminosilane inhibitor adsorbs to the first material. The aminosilane inhibitor may be presented to the substrate surface as a dry aminosilane inhibitor. In other words, the aminosilane inhibitor would not be dissolved or suspended in a solvent prior to being exposed to the substrate surface.

In various examples, the aminosilane inhibitor molecule can comprise one or more of dimethylamino trimethyl silane, dimethylamino dimethyl silane, dimethylamino triethyl silane, diethylamino trimethylsilane, n-butyldimethyl(dimethylamino)silane, n-propyldimethyl(dimethylamino)silane, or triisopropyldimethylaminosilane. More generally, the aminosilane inhibitor can comprise any suitable aminosilane having a general formula of R₁R₂N—SiR₃R₄R₅, where R₃, R₄, and Rs are unreactive, hydrophobic, and sterically hinder deposition on the inhibited layer. Following the plasma pretreatment, the adsorbed aminosilane inhibitor molecule can selectively passivate dielectrics such as silicon dioxide, silicon oxynitride, silicon oxycarbide, silicon nitride, or cobalt with respect to other materials, such as tungsten, copper, molybdenum, titanium nitride, or tungsten oxide.

FIG. 4C illustrates the substrate surface 404 comprising adsorbed aminosilane inhibitor 412. Aminosilane inhibitor 412 adsorbs to second material 408. However, aminosilane inhibitor 412 does not adsorb to first material 406 sufficiently to inhibit subsequent film growth.

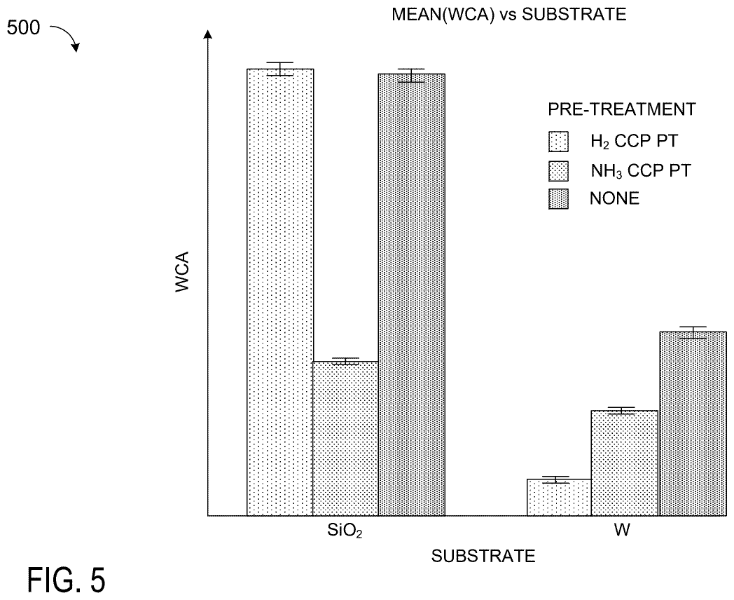

FIG. 5 shows an example bar graph 500 comprising experimental data regarding enhancements in selectivity for an example aminosilane inhibitor (dimethylamino trimethylsilane) between SiO₂ and Was determined by water contact angle (WCA) following aminosilane inhibitor exposure. For SiO₂, a plasma pretreatment with H₂ CCP yielded a WCA that was similar to no pretreatment at all. In contrast, pretreatment of SiO₂ with ammonia (NH₃) CCP significantly reduced WCA, thus reducing inhibitor adhesion. For W, pretreatment with H₂ CCP yielded a lower WCA than pretreatment of W with NH₃ CCP, which was lower than no pretreatment at all. It can be seen that, when omitting a plasma pretreatment, some undesired inhibitor adsorption occurs on the W surface.

It has been found that H₂ plasma pretreatment does not significantly affect the WCA for SiO₂, while H₂ plasma pretreatment reduces the WCA for W. NH₃ CCP pretreatment (PT) reduces adsorption of the aminosilane inhibitor to silicon dioxide. H₂ CCP PT was found to enhance the WCA contrast between silicon dioxide and W. It will be noted that, while ammonia reduced WCA for SiO₂, ammonia may be effective in providing selectivity for other sets of materials than SiO₂ and W.

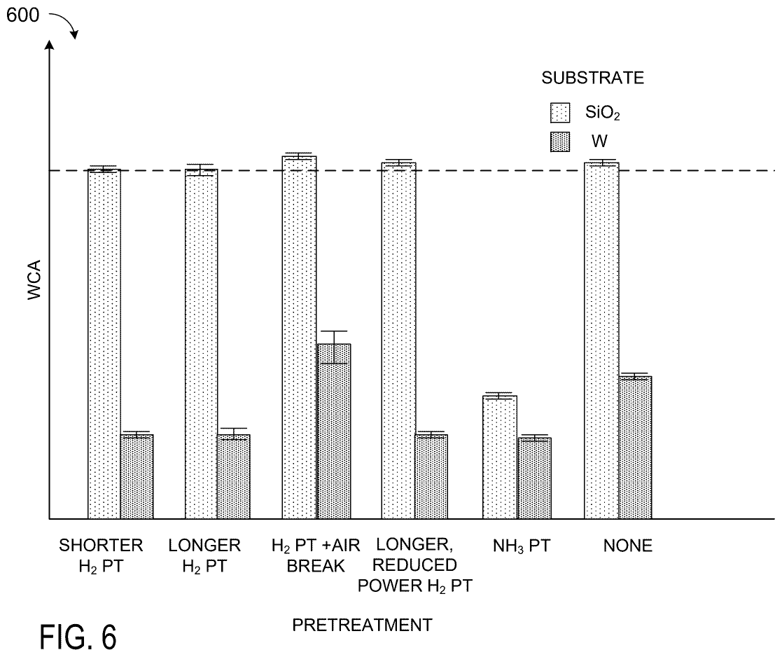

FIG. 6 shows a bar graph 600 indicating experimental data regarding the relative effects of different plasma pretreatment protocols on selective adsorption of aminosilane inhibitor to SiO₂ compared to W, as indicated by mean WCA. SiO₂ and W substrates were subject to the following different plasma pretreatments: a shorter H₂ CCP pretreatment, a longer H₂ CCP pretreatment, a CCP H₂ pretreatment with an air break prior to aminosilane inhibitor exposure, a longer H₂ CCP pretreatment at a relatively lower RF power than other H₂ experiments, an NH₃ CCP pretreatment, and no pretreatment. In all examples, aminosilane inhibitor exposure was performed under the same or similar conditions. As shown, without any pretreatment, WCA on W indicates some undesired inhibitor adsorption. Inserting an air break between PT and aminosilane inhibitor exposure can re-oxidizes W, and result in more aminosilane inhibitor adsorption to the W. As such, avoiding air breaks can help to increase selectivity and the efficacy of pretreatment compared to the use of air breaks. This provides dry treatment processes with an advantage over previous, wet treatment processes that required air breaks.

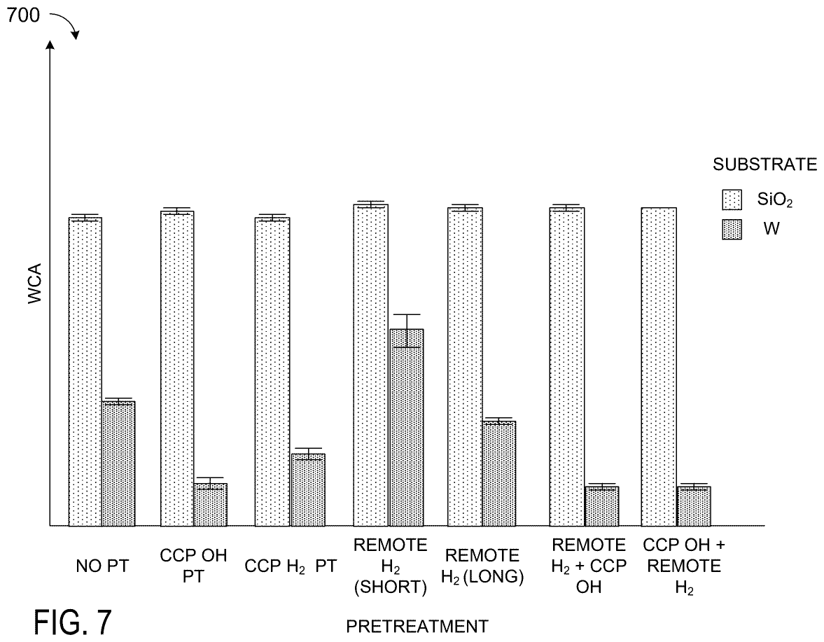

FIG. 7 is a bar graph 700 illustrating the selectivity of an example aminosilane inhibitor (dimethylamino trimethylsilane) to SiO₂ with respect to W as a function of different example plasma pretreatments as indicated by mean WCA. Substrates were subject plasma pretreatment followed by aminosilane inhibitor exposure. Substrates were exposed to no pretreatment, CCP OH pretreatment, CCP H₂ pretreatment, H₂ remote plasma (shorter duration) pretreatment, H₂ remote plasma (longer duration) pretreatment, H₂ remote plasma pretreatment followed by CCP OH pretreatment, and CCP OH pretreatment followed by remote H₂ pretreatment. In all examples, aminosilane inhibitor exposure was performed under the same or similar conditions.

As shown, CCP OH pretreatment increases selectivity for the aminosilane inhibitor relative to no pretreatment. Remote H₂ plasma pretreatment results in an increased WCA on W in some conditions. Combining H₂ remote plasma pretreatment plus CCP OH pretreatment resulted in the largest WCA contrast.

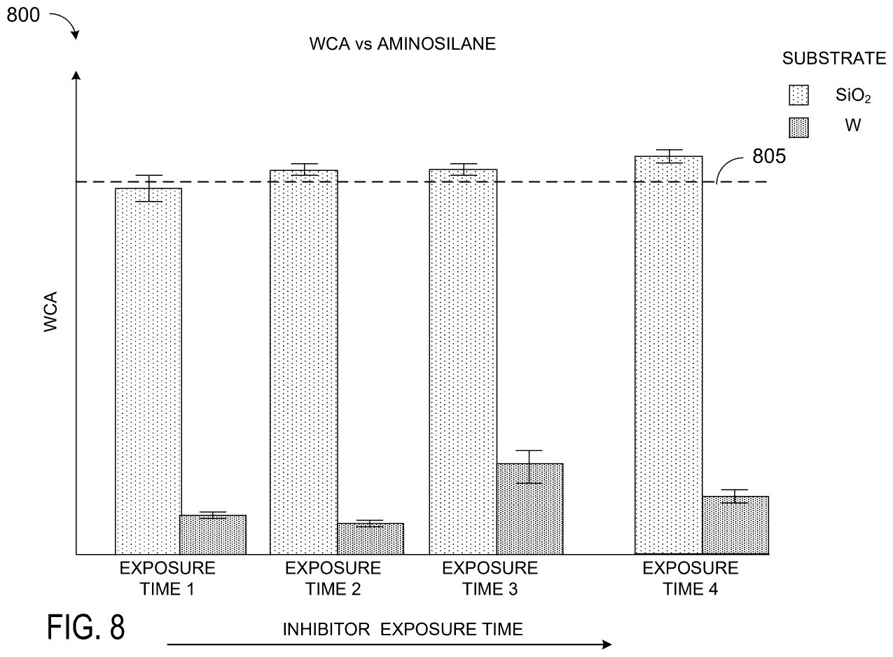

FIG. 8 shows an example bar graph 800 illustrating adsorption of an example aminosilane inhibitor as a function of a duration of aminosilane inhibitor exposure. Exposure time 1 was the shortest exposure time, followed by exposure time 2, exposure time 3, and exposure time 4 was the longest. As shown, the WCA of aminosilane inhibitor on SiO₂ increases as a function of exposure time. The WCA of W remains low, with a slight increase at exposure time 3. This indicates that even a brief CCP H₂ treatment is sufficient to differentiate aminosilane inhibitor adsorption between SiO₂ and W.

Returning to FIG. 3, at 330, method 300 comprises depositing a film onto the substrate surface. The aminosilane inhibitor on the second material inhibits deposition of the film onto the second material as compared to deposition of the film on the first material. For example, depositing the film can comprise depositing the film using atomic layer deposition. In some examples, the film is a dielectric film. Such a dielectric film can comprise one or more of aluminum oxide, silicon nitride, titanium oxide, zinc oxide, silicon dioxide, hafnium oxide, tin oxide, titanium nitride, tantalum nitride, or rubidium. Additionally or alternatively, the film may comprise tungsten, molybdenum, tantalum, cobalt, copper, or any other suitable conductive metal, alloy, or compound.

Referring to FIG. 4D, following exposure to aminosilane inhibitor 412, film 414 is deposited onto substrate surface 404. With second material 408 inhibited, film 414 is deposited selectively onto first material 406. At FIG. 4E, aminosilane inhibitor 412 is removed from second material 408, yielding a clean substrate having a delineated film 414. Aminosilane inhibitor 412 can be removed, for example, using a suitable plasma treatment. Examples include H₂, OH, BCl₃/HBr, NH₃, and O₂ plasmas.

By utilizing a plasma pretreatment followed by aminosilane inhibitor exposure, a subsequent film can be selectively deposited onto a desired substrate surface without an air break following the exposure of the substrate surface to the aminosilane inhibitor.

An additional benefit of method 300 is that no rinse step (wet or dry) is needed after the inhibitor treatment to enable selective adsorption of the inhibitor to the dielectrics. This mitigates the potential defects caused by incomplete inhibitor removal during rinsing on the desired growth surfaces. This also eliminates the need for wet processing (thus eliminating the need for multiple chambers to treat a single substrate, thereby reducing process complexity and cost, and increasing potential throughput.

Further, in some examples, a dilute wet etch of the substrate may be performed prior to plasma pretreatment. This enables the process to occur without an air break following plasma pretreatment. Subsequent aminosilane inhibitor exposure can further improve dielectric film growth on SiO₂. An example dilute wet etch is a dilute HF etch.

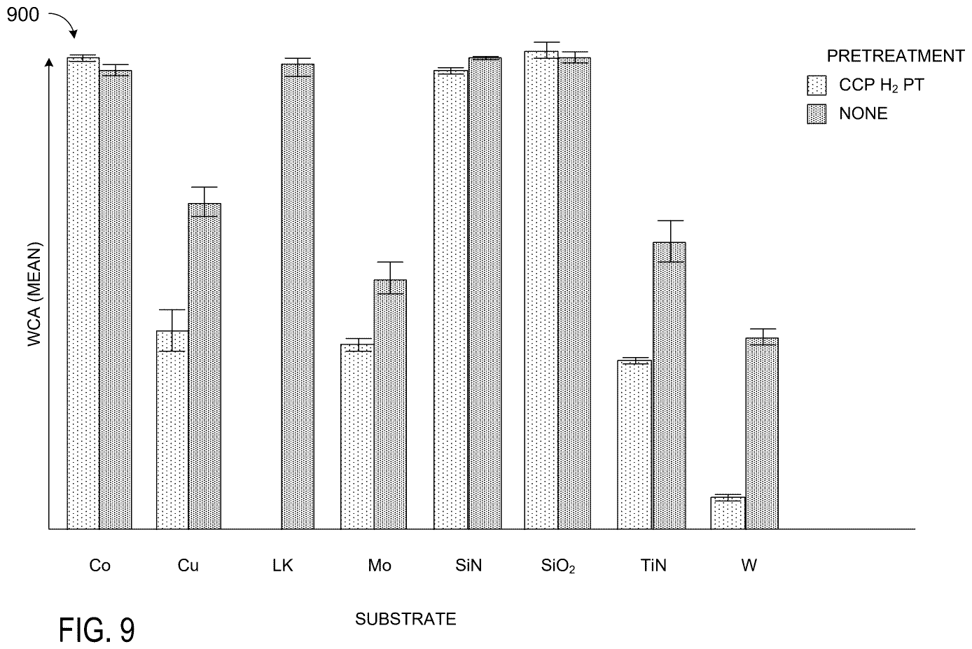

FIG. 9 is an example bar graph 900 indicating adsorption of an example aminosilane precursor to different substrate materials with and without an example plasma pretreatment. As shown, different substrate materials were pretreated with CCP H₂ or were not subject to pretreatment, followed by aminosilane inhibitor exposure. As shown, CCP H₂ pretreatment did not significantly affect aminosilane inhibitor adsorption to SiO₂, SiN, or Co. However, significantly less reactivity was observed between aminosilane inhibitor and Cu, Mo, TiN, and W. As such, CCP H₂ pretreatment may be used to generate selectivity between one or more of Co, low-k dielectric (LK) (e.g., SiON. SiOC, SiCN, or SiCON), SiN, and SiO₂ and one or more of Cu, Mo, TiN, and W.

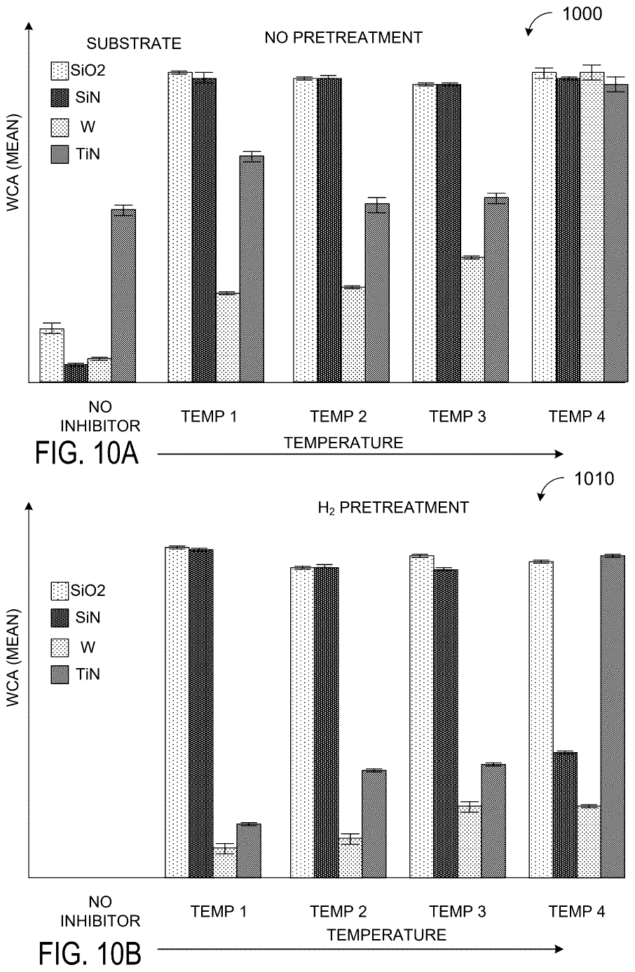

FIGS. 10A-10B show bar graphs 1000 and 1010, respectively, illustrating effects of substrate temperature on selectivity of an example aminosilane inhibitor (dimethylamino trimethylsilane) as indicated by WCA. FIG. 10A shows adsorption based on substrate temperature with no pretreatment, and FIG. 10B shows adsorption based on substrate temperature with CCP pretreatment.

As shown in FIGS. 10A and 10B, with or without pretreatment, aminosilane inhibitor selectively adsorbs to dielectrics SiO₂ and SiN compared to TiN and W over a range of increasing temperatures. As shown in FIG. 10A, at temperature 4, without pretreatment, aminosilane inhibitor adsorbs to all surfaces, thereby substantially losing selectivity. As shown in FIG. 10B, H₂ CCP pretreatment reduces aminosilane inhibitor adsorption to W surfaces at all temperatures. H₂ CCP pretreatment also reduces aminosilane inhibitor adsorption with TiN below temperature 4.

In some processes, over the course of several cycles of atomic layer deposition of the film being selectively deposited after aminosilane exposure, the aminosilane can become depleted. Thus, in such examples, the aminosilane inhibitor can be reapplied during the film deposition process as needed. Such intermediate re-exposure of the substrate to the aminosilane inhibitor can be referred to as super cycling. One supercycle comprises an aminosilane exposure followed by a plurality of atomic layer deposition cycles. A new super cycle can be initiated, for example, after a pre-determined number of dielectric film deposition cycles and/or based on operating conditions (e.g., dielectric film thickness).

Returning to FIG. 3, at 340, method 300 optionally comprises, prior to re-exposing the substrate surface to the aminosilane inhibitor, removing at least some aminosilane inhibitor adsorbed to the substrate surface. For example the aminosilane inhibitor may be removed by exposure to an H₂ plasma.

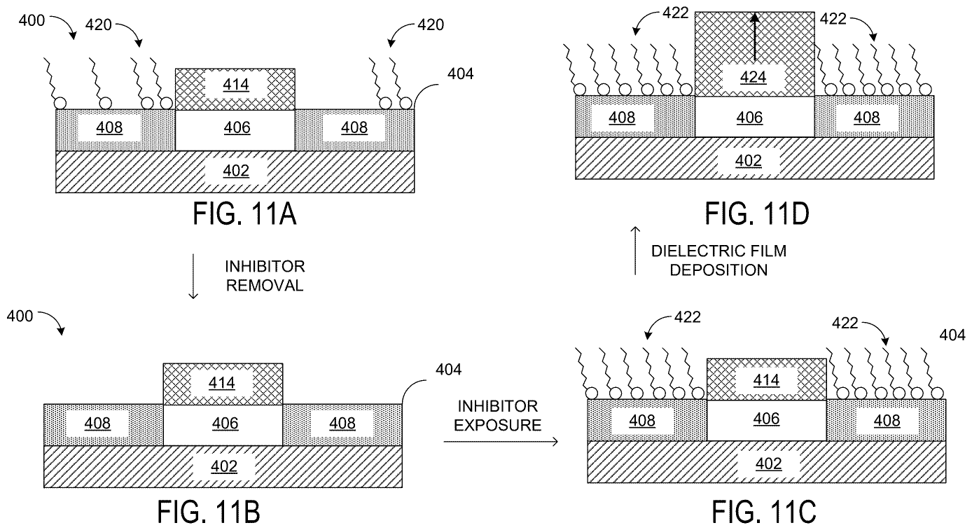

As an example, FIGS. 11A-11D show cross-sectional views of substrate 400 at various stages in a super-cycled dielectric film deposition process. As described with regard to FIGS. 4A-4E, substrate 400 comprises an underlayer 402 of arbitrary composition, and substrate surface 404. Substrate surface 404 comprises first material 406 and second material 408. A film 414 has been deposited on first material 406. In the example of FIG. 11A, a depleted aminosilane inhibitor layer 420 is adsorbed to second material 408. In FIG. 11B, depleted aminosilane inhibitor layer 420 has been removed.

Returning to FIG. 3, at 350, method 300 includes, following deposition of the film onto the substrate surface, re-exposing the substrate surface to the aminosilane inhibitor. Aminosilane inhibitor may be adsorbed to dielectric surfaces using the same, similar, or differing methods than those described at 320. For example, the substrate surface may be re-exposed to a dry aminosilane inhibitor. As an example, FIG. 11C shows a new aminosilane inhibitor layer 422 adsorbed to second material 408.

Returning to FIG. 3, at 360, method 300 includes performing an additional deposition of the film onto the substrate surface. As described at 330, the aminosilane inhibitor on the dielectric surface inhibits deposition of the film onto second material 408 as compared to deposition of the film on first material 406. As an example, FIG. 11D shows an increased film 424 on first material 406, with no film deposited onto second material 408.

FIG. 12 schematically shows an example computing system 1200 that can enact one or more of the methods and processes described above. Computing system 1200 is shown in simplified form. Computing system 1200 may take the form of one or more personal computers, workstations, computers integrated with substrate processing tools, and/or network accessible server computers.

Computing system 1200 includes a logic machine 1202 and a storage machine 1204. Computing system 1200 may optionally include a display subsystem 1206, input subsystem 1208, communication subsystem 1210, and/or other components not shown in FIG. 12. Controllers 140 and 229 are examples of computing system 1210.

Logic machine 1202 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 1204 includes one or more physical devices configured to hold instructions 1212 executable by the logic machine to implement the methods and processes described herein. When such methods and processes are implemented, the state of storage machine 1204 may be transformed—e.g., to hold different data.

Storage machine 1204 may include removable and/or built-in devices. Storage machine 1204 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1204 may include volatile, nonvolatile, dynamic, static, read/write, read-only, random-access, sequential-access, location-addressable, file-addressable, and/or content-addressable devices.

It will be appreciated that storage machine 1204 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 1202 and storage machine 1204 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1206 may be used to present a visual representation of data held by storage machine 1204. This visual representation may take the form of a graphical user interface (GUI). As the herein described methods and processes change the data held by the storage machine, and thus transform the state of the storage machine, the state of display subsystem 1206 may likewise be transformed to visually represent changes in the underlying data. Display subsystem 1206 may include one or more display devices utilizing virtually any type of technology. Such display devices may be combined with logic machine 1202 and/or storage machine 1204 in a shared enclosure, or such display devices may be peripheral display devices.

When included, input subsystem 1208 may comprise or interface with one or more user-input devices such as a keyboard, mouse, or touch screen. In some examples, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 1210 may be configured to communicatively couple computing system 1200 with one or more other computing devices. Communication subsystem 1210 may include wired and/or wireless communication devices compatible with one or more different communication protocols. As non-limiting examples, the communication subsystem may be configured for communication via a wireless telephone network, or a wired or wireless local- or wide-area network. In some examples, the communication subsystem may allow computing system 1200 to send and/or receive messages to and/or from other devices via a network such as the Internet.

It will be understood that the configurations and/or approaches described herein are exemplary in nature, and that these specific examples or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for selectively depositing a film onto a first material of a substrate surface, the substrate surface also comprising a second material, the method comprising:
exposing the substrate surface to reactive species formed in a plasma;
after exposing the substrate surface to the reactive species formed in the plasma, exposing the substrate surface to an aminosilane inhibitor, thereby adsorbing the aminosilane inhibitor to the substrate surface, wherein the aminosilane inhibitor adsorbs to the second material in a higher concentration than the aminosilane inhibitor adsorbs to the first material; and
depositing the film onto the substrate surface, wherein the aminosilane inhibitor on the second material inhibits deposition of the film onto the second material as compared to deposition of the film on the first material.

2. The method of claim 1, wherein aminosilane inhibitor is a dry aminosilane inhibitor, and wherein the substrate surface is exposed to the dry aminosilane inhibitor without an air break following the exposure of the substrate surface to the reactive species formed in the plasma.

3. The method of claim 1, further comprising:
following deposition of the film onto the substrate surface, re-exposing the substrate surface to the aminosilane inhibitor; and
performing an additional deposition of the film onto the substrate surface.

4. The method of claim 3, further comprising:
prior to re-exposing the substrate surface to the aminosilane inhibitor, removing at least some aminosilane inhibitor adsorbed to the substrate surface.

5. The method of claim 1, wherein depositing the film comprises depositing the film using atomic layer deposition.

6. The method of claim 1, wherein the second material comprises a dielectric material, and wherein the first material comprises a metal material.

7. The method of claim 1, wherein the second material comprises one or more of silicon dioxide, silicon oxynitride, silicon oxycarbide, silicon nitride, or cobalt, and wherein the first material comprises one or more of tungsten, copper, molybdenum, titanium nitride, or tungsten oxide.

8. The method of claim 1, wherein the aminosilane inhibitor comprises one or more of dimethylamino trimethyl silane, dimethylamino dimethyl silane, dimethylamino triethyl silane, diethylamino trimethylsilane, n-butyldimethyl(dimethylamino)silane, n-propyldimethyl(dimethylamino)silane, or triisopropyldimethylaminosilane.

9. The method of claim 1, wherein the film is a dielectric film that comprises one or more of aluminum oxide, silicon nitride, titanium oxide, zinc oxide, silicon dioxide, hafnium oxide, tantalum nitride or titanium nitride.

10. The method of claim 1, wherein exposing the substrate surface to the reactive species formed in the plasma comprises exposing the substrate surface to one or more of a capacitively coupled H₂/O₂ plasma, a capacitively coupled H₂ plasma, or a capacitively coupled He plasma.

11. The method of claim 1, wherein exposing the substrate surface to the reactive species formed in the plasma comprises exposing the substrate surface to radicals generated in a remote plasma.

12. A processing tool comprising:
a processing chamber;
a substrate support within the processing chamber, the substrate support configured to support a substrate;
flow control hardware operable to control a flow of one or more processing chemicals to the processing chamber;
a radiofrequency power source configured to generate a plasma; and
a controller configured to control the processing tool to:
operate the radiofrequency power source and the flow control hardware to expose the substrate, the substrate comprising a substrate surface with a first material and a second material, to reactive species formed in the plasma;
after operating the radiofrequency power source and the flow control hardware to expose the substrate surface to the reactive species formed in the plasma, operate the flow control hardware to control a flow of an aminosilane inhibitor from an aminosilane inhibitor source to expose the substrate surface to the aminosilane inhibitor, wherein the aminosilane inhibitor is configured to adsorb to the second material in a higher concentration than the first material; and
operate the flow control hardware to control a flow of a dielectric film precursor from a dielectric film precursor source to deposit a dielectric film onto the substrate surface.

13. The processing tool of claim 12, wherein the controller is further configured to control the flow control hardware to deposit the dielectric film onto the substrate surface without an air break following controlling the flow control hardware to expose the substrate surface to the aminosilane inhibitor.

14. The processing tool of claim 12, wherein the controller is further configured to control the processing tool to:
following controlling the flow control hardware to deposit the dielectric film onto the substrate surface, operate the flow control hardware to control the flow of the aminosilane inhibitor from the aminosilane inhibitor source to re-expose the substrate surface to the aminosilane inhibitor, and
operate the flow control hardware to control the flow of dielectric film precursors from the dielectric film precursor source to perform a second deposition of the dielectric film onto the substrate surface.

15. The processing tool of claim 14, wherein the controller is further configured to control the processing tool to:
prior to re-exposing the substrate surface to the aminosilane inhibitor, control the flow control hardware and the plasma generator to remove at least some aminosilane inhibitor adsorbed to the substrate surface.

16. The processing tool of claim 12, wherein the controller is further configured to control the processing tool to deposit the dielectric film using atomic layer deposition.

17. The processing tool of claim 12, wherein the controller is further configured to operate the radiofrequency power source to expose the substrate surface to one or more of a capacitively coupled H₂/O₂ plasma, a capacitively coupled H₂ plasma, or a capacitively coupled He plasma.

18. The processing tool of claim 12, wherein the controller is configured to operate the radiofrequency power source to expose the substrate surface to the plasma by operating the radiofrequency power source to expose the substrate surface to radical species from a remote plasma.

19. A method for selectively depositing a dielectric film onto a substrate surface comprising a dielectric material and a metal material, the method comprising:
exposing the substrate surface to reactive species formed in a plasma;
after exposing the substrate surface to the plasma, exposing the substrate surface to a dry aminosilane inhibitor, the dry aminosilane inhibitor comprising one or more of dimethylamino trimethyl silane, dimethylamino dimethyl silane, dimethylamino triethyl silane, diethylamino trimethylsilane, n-butyldimethyl(dimethylamino)silane, n-propyldimethyl(dimethylamino)silane, or triisopropyldimethylaminosilane thereby adsorbing the dry aminosilane inhibitor to the substrate surface, wherein the dry aminosilane inhibitor adsorbs to the dielectric material in a higher concentration than the dry aminosilane inhibitor adsorbs to the metal material; and
without an air break following the exposure of the substrate surface to the dry aminosilane inhibitor, depositing the dielectric film onto the substrate surface, wherein the dry aminosilane inhibitor on the dielectric material inhibits deposition of the dielectric film onto the dielectric material as compared to deposition of the dielectric film on the metal material.

20. The method of claim 19, wherein the dielectric material comprises SiO₂, and wherein the metal material comprises tungsten.
